(19) United States
(12) Patent Application Publication
(10) Pub. No.: US 2013/0100675 A1
(43) Pub. Date: Apr. 25, 2013

(54) MULTI-FUNCTIONAL GLASS WINDOW WITH PHOTOVOLTAIC AND LIGHTING FOR BUILDING OR AUTOMOBILE

(71) Applicants: Sijin Han, Milpitas, CA (US); Fan Yang, Sunnyvale, CA (US)

(72) Inventors: Sijin Han, Milpitas, CA (US); Fan Yang, Sunnyvale, CA (US)

(73) Assignee: QUALCOMM MEMS TECHNOLOGIES, INC., San Diego, CA (US)

(21) Appl. No.: 13/281,060

(22) Filed: Oct. 25, 2011

(51) Int. Cl. F21V 33/00; H01L 31/18; H01L 31/042; H05B 33/02; H01L 31/0376; H01L 31/0224

(52) U.S. Cl. 362/253; 136/258; 136/256; 136/244; 313/498; 438/98; 257/E31.126

(57) ABSTRACT

The present disclosure describes multi-functional windows. Functions of the multi-functional windows described herein can include transmitting incident light, generating photovoltaic power from incident light, and emitting light. In some implementations, a multi-functional window may be placed in a photovoltaic state, a lighting state, or a neutral state. A multi-functional window can continue to function as a normal window in transmitting a portion of any incident light in any of the photovoltaic, lighting, and neutral states. A multi-functional window can be implemented in a building or automobile.

### TECHNICAL FIELD

This disclosure relates generally to photovoltaic and lighting technologies and more specifically to windows that include functionalities such as lightning and power generation.

### BACKGROUND

Photovoltaics generate electrical power by converting solar radiation into direct current electricity using semiconductors that exhibit the photovoltaic effect. Building-integrable photovoltaics are photovoltaics that are integrated during the building of a structure. Current building-integrable photovoltaics include conventional solar modules integrated into roof or façade of a structure.

Light emitting diode (LED) lighting generates light using semiconductors that exhibit electroluminescence. Building-integrable photovoltaics and light emitting diode (LED) lighting are two components of resource-efficient buildings. To date, however, photovoltaic and lighting functions have not been integrated into windows, which represent a significant portion of a building envelope.

### SUMMARY

The systems, methods and devices of the disclosure each have several innovative aspects, no single one of which is solely responsible for the desirable attributes disclosed herein.

One innovative aspect of the subject matter described in this disclosure is a multi-functional window. Window functions can include transmitting incident light, generating photovoltaic power from incident light, and producing lighting. In some implementations, a multi-functional window may be placed in a photovoltaic state, a lighting state, or a neutral state. In some implementations, the window can continue to function as a normal window in transmitting a portion of any incident light while in any of the photovoltaic, lighting, and neutral states.

Another innovative aspect of the subject matter described in this disclosure is a window including first and second transparent substrates, a photovoltaic module disposed between the first transparent substrate and the second transparent substrate, and a lighting module disposed between the first transparent substrate and second transparent substrate. The photovoltaic module can include a first transparent electrode and one or more photovoltaic active thin film layers and the lighting module can include a second transparent electrode and one or more electroluminescent active layers. Each of the photovoltaic module and the lighting module can further include a grid electrode disposed between the photovoltaic active thin film layers and the electroluminescent active layers. The photovoltaic module and the lighting module can share a grid electrode, or have separate grid electrodes.

In some implementations, the window can be configured to transmit at least a portion of incident light bi-directionally. In some implementations, the window is switchable between a photovoltaic state and a lighting state. In a photovoltaic state, the window is operable to convert a first portion of incident light to electrical energy and transmit a second portion of incident light. In a lighting state, the window is operable to generate and emit light. In some implementations, the window can be further switchable to and from a neutral state in which the window is electrically disconnected and transmits a portion of the incident light.

Another innovative aspect of the subject matter described in this disclosure is a window including means for transmitting incident light, means for generating power from incident light, and means for producing lighting. In some implementations, the means for transmitting incident light include means for transmitting between about 20% and 50% of incident light. In some implementations, the window can further include means for switching between a photovoltaic state and a lighting state.

Another innovative aspect of the subject matter described in this disclosure is a method for fabricating a multi-functional window. The method can include depositing one or more thin film layers selected from transparent conducting oxide layers and thin film photovoltaic layers on a first transparent pane, depositing one or more thin film layers selected from transparent conducting oxide layers and thin film electroluminescent layers on a second transparent pane, and placing one or more metal grids between the thin film layers deposited on the first transparent substrate and the thin film layers deposited on the second transparent substrate to form a pane and grid assembly. The method can further include framing the pane and grid assembly.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIGS. 1A and 1B show examples of schematic illustrations of multi-functional window integrated into a building in various states.

FIG. 2 shows an example of a cross-sectional schematic illustration of a multi-functional window.

FIGS. 3A-3C shows examples of cross-sectional schematic illustrations of a photovoltaic module of a multi-functional window.

FIGS. 4A and 4B shows examples of cross-sectional schematic illustrations of a lighting module of a multi-functional window.

FIG. 5 shows an example of a schematic illustration of a multi-functional window including two metal grid cathodes.

FIGS. 6A and 6B show examples of schematic illustrations of multi-functional windows having various state-switching configurations.

FIGS. 7A and 7B show examples of schematic illustrations of top (external pane-facing) views of photovoltaic modules of a multi-functional window.

FIGS. 8A-8D show examples of schematic illustrations of cross-sectional views of photovoltaic modules including multiple photovoltaic cells and equivalent circuit diagrams of the same.

FIGS. 9A and 9B show examples of schematic illustrations of top (internal pane-facing) views of lighting modules of a multi-functional window.

FIGS. 10A and 10B show examples of a schematic illustration of top view of a cathode of a multi-functional window.

FIGS. 11A-11D show examples of schematic illustrations of a cross-sectional view of portions of cathodes of multi-functional windows.

FIG. 12 is a graph depicting the light transmission percentages of windows including photovoltaic thin film layers of different thicknesses and electroluminescent thin film layers of fixed thicknesses.

FIG. 13 shows an example of a flow diagram illustrating a manufacturing process for a multi-functional window.

FIG. 14 shows an example of a cross-sectional schematic illustration of a multi-functional window.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any window, including windows in buildings and automobiles. The teachings are not intended to be limited to the implementations depicted solely in the Figures, but instead have wide applicability as will be readily apparent to one having ordinary skill in the art.

Some implementations provide a multi-functional window. Window functions can include transmitting incident light, generating photovoltaic power from incident light, and producing lighting. In some implementations, the window may be placed in a photovoltaic state, a lighting state, or a neutral state. In any state, the window can continue to function as a normal window in transmitting a portion of any incident light. For example, between about 10-90% of incident light can be transmitted.

In some implementations, a window includes exterior and interior panes, with a photovoltaic module and a lighting module disposed between the exterior and interior panes. The photovoltaic modules and lighting module can share a common metal electrode. The window can be switched between a photovoltaic state, a lighting state, and a neutral state. During the day, the window can transmit incident sunlight to the interior of a building, car, or other enclosed area, and simultaneously generate power using the photovoltaic module. During times when sunlight is not incident, for example during night or overcast conditions, the window can emit light to illuminate the interior of the building, car, or other enclosed area.

Particular implementations of the subject matter described in this disclosure can be implemented to realize one or more of the following potential advantages. In some implementations, the multi-functional windows can reduce or eliminate reliance on non-renewable energy sources. In some implementations, the multi-functional windows can be tinted in desired shades, improving indoor aesthetics, reducing light and heat transmission, and reducing air conditioning usage. In some implementations, energy efficient white or colored lighting can be produced.

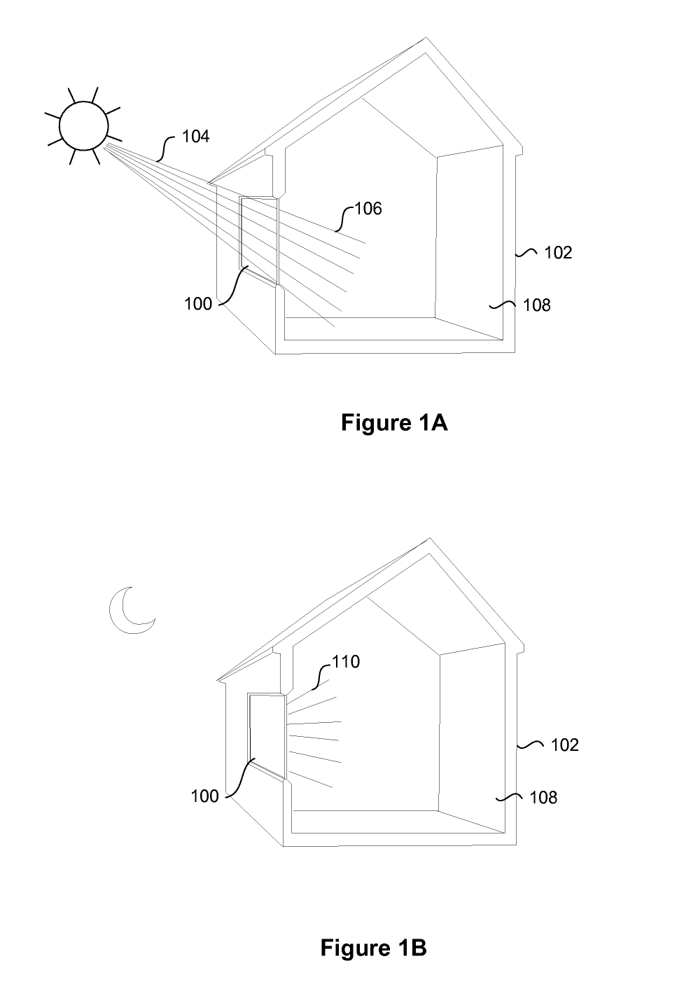

FIGS. 1A and 1B show examples of schematic illustrations of multi-functional window integrated into a building during various states. First, in FIG. 1A a multi-functional window 100 integrated into a building 102 is shown during daytime. (For clarity, a cutaway view of the building 102 is depicted without a front wall.) Incident light 104 from the sun is incident on the multi-functional window 100. The multi-functional window 100 transmits at least a portion of the incident light 104 into an interior 108 of the building 102. In some implementations, the transmitted light 106 ranges between about 10% to about 90% of the incident light 104. The multi-functional window can have a tinted appearance in some implementations, with the color and tint characteristics tunable as described further below. In addition to transmitting a portion of the incident light 104, the multi-functional window 100 can absorb a portion of the incident light 104 and convert it to electrical energy. The generated energy can be stored in a battery, provide power to the building 102, connected to a grid, or otherwise used according to the desired implementation.

FIG. 1B shows the multi-functional window 100 during nighttime. In the example of FIG. 1B, the multi-functional window 100 is shown in a lighting state and emits emitted light 110, which illuminates the interior 108 of the building 102. The emitted light 110 can be white or colored light according to the desired implementation. In the depicted example, there is no significant exterior or interior light incident on the multi-functional window. However, if light from the exterior or interior of the building 102 is incident on the multi-functional window 100, a portion of the incident light can be transmitted through the multi-functional window 100 while it is in a lighting state.

While the building 102 in FIGS. 1A and 1B is a residential-type building, the multi-functional windows described herein can be integrated into any type of structure, including office buildings, commercial buildings, residential buildings, and the like. The multi-functional windows described herein can also be integrated into vehicles including automobiles, trucks, trains, planes, and the like.

In some implementations, a plurality of multi-functional windows can be integrated into a building. For example, the windows of an office building can be multi-functional windows as described herein. The multi-functional windows can contribute to resource-efficiency in a variety of ways including reducing incident electromagnetic radiation that is transmitted through a window and associated air conditioning, generating energy for building use, reducing external energy usage, and providing low energy lighting.

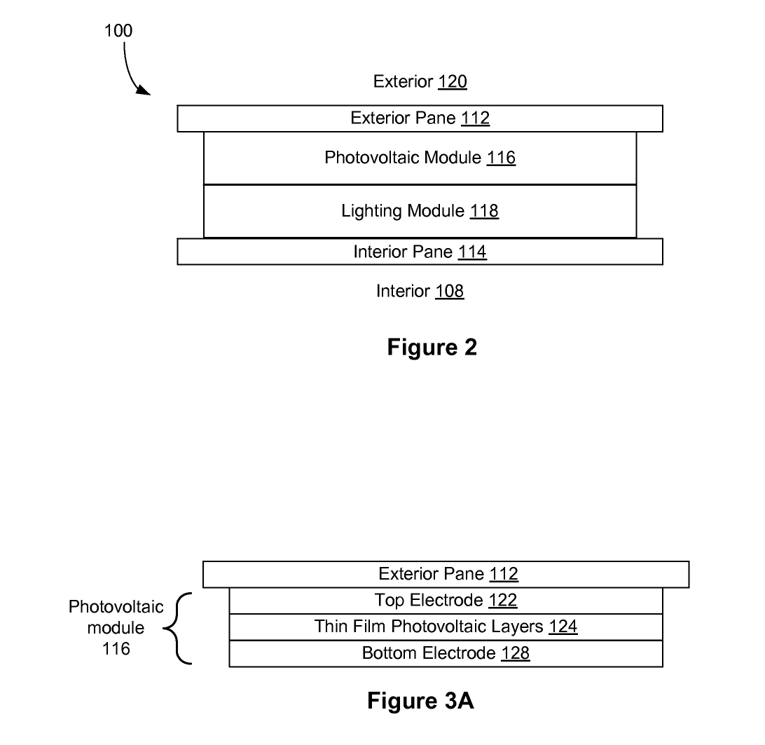

FIG. 2 shows an example of a cross-sectional schematic illustration of a multi-functional window. The multi-functional window 100 includes an exterior pane 112 and an interior pane 114. Exterior and interior panes 112 and 114 can be glass, plastic, or any other material that is transparent to visible light. Between the exterior pane 112 and the interior pane 114 are two modules: a photovoltaic module 116 and a lighting module 118. The photovoltaic module 116 is configured to absorb light that passes through the exterior pane 112 and convert it to electrical energy. The lighting module 118 is configured generate light using supplied power and emit the generated light through interior pane 114. In some implementations, the multi-functional window also permits light to pass through it bi-directionally. For example, in some implementations, at least 10% of the light incident on the multi-functional window 100 from the exterior 120 and the interior 108 of the building can pass through the multi-functional window 100.

In many implementations, the thicknesses of the exterior and interior panes 112 and 114 provide most of the thickness of the multi-functional window 100. The total thickness of the multi-functional window 100 can range from about 6 mm to about 15 mm in some implementations, with the thickness of each pane ranging from about 3 mm to about 7.5 mm. In many embodiments, the thicknesses of each of the photovoltaic module 116 and the lighting module 118 is relatively small, being on the order of tens of microns. The total thickness of the multi-functional window 100, and the thicknesses of the individual panes, can be outside of these ranges according to the desired implementation. For example, a multi-functional window 100 can include an air gap of 1 mm or greater between the photovoltaic module 116 and the lighting module 118.

According to various implementations, one or both of photovoltaic and lighting modules of a multi-functional window can be activated. In some implementations, a multi-functional window is switchable between the following states: a neutral state in which neither the photovoltaic module nor the lighting module is activated, a photovoltaic state in which the photovoltaic module is activated, and a lighting state in which the lighting module is activated. Table 1, below, summarizes certain functions of a multi-functional window according to some implementations:

TABLE 1
Functionalities of a Multi-Functional Window in Various States

| | Neutral | Photovoltaic | Lighting |
|---|---|---|---|
| | State | State | State |
| Bi-directional transmission of | yes | yes | yes |
| incident light | | | |
| Photovoltaic power generation | no | yes | no |
| Light generation | no | no | yes |

In the implementation described in Table 1, a multi-functional window in a neutral state can transmit light bi-directionally, i.e., from the exterior of a structure to its interior and vice versa. For example, during daylight, sunlight can be transmitted into a building and during nighttime, for example, light from lamps within the building can be transmitted to the outside of the building. Typically only a portion of light incident on a multi-functional window is transmitted, with the remainder absorbed within the multi-functional window. In a photovoltaic state, a multi-functional window can transmit light bi-directionally. In addition, at least some of the absorbed light that is not transmitted can be converted to electrical power by the photovoltaic module. In a lighting state, a multi-functional window can transmit light bi-directionally, as described above, as well as emit light into the interior of the structure. In use, a lighting state may be used primarily or exclusively during night, overcast conditions and other times when there is relatively little or no light being transmitted from the exterior of a structure.

Table 1 describes functionalities of a photovoltaic state and a lighting state in implementations in which only one of the photovoltaic module and lighting module can be activated at a time. In some other implementations, the photovoltaic and lighting modules can be activated at the same time, such that a multi-functional window can simultaneously generate power and emit light.

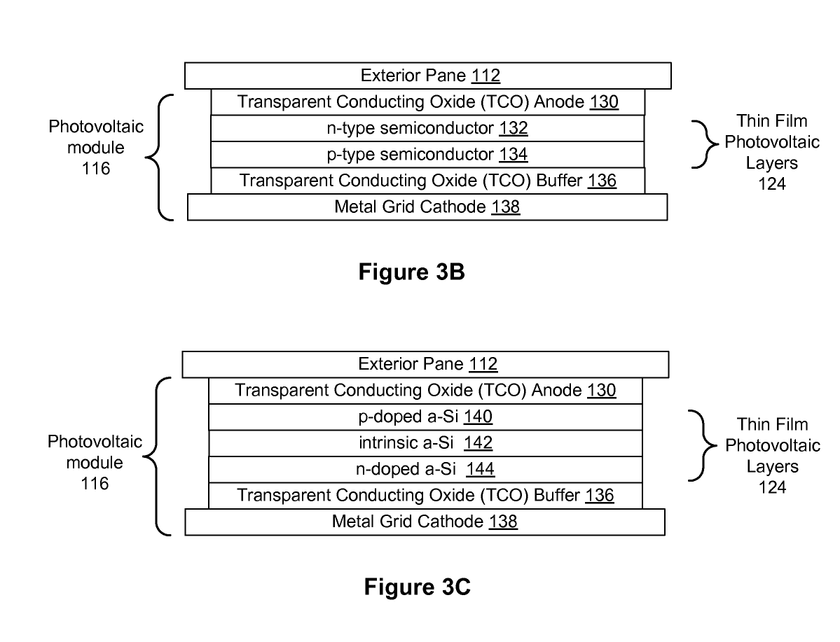

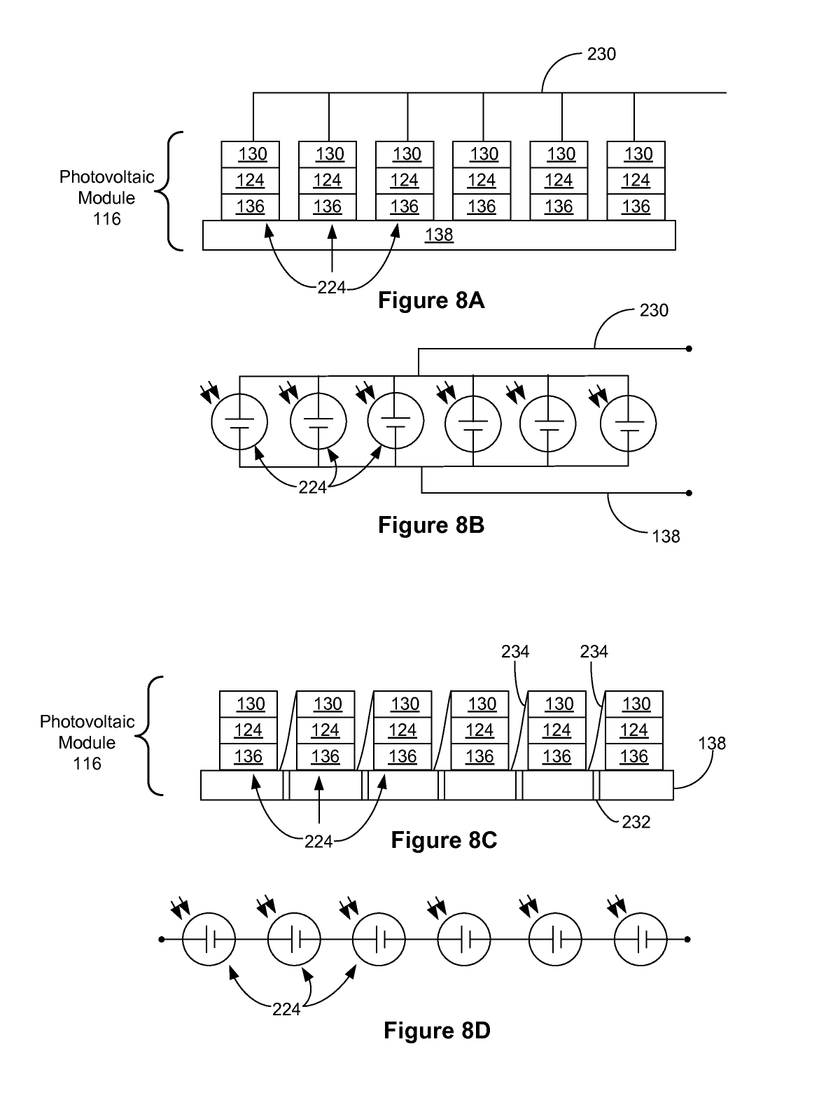

FIGS. 3A-3C shows examples of cross-sectional schematic illustrations of a photovoltaic module of a multi-functional window. It should be noted that FIGS. 3A-3C represent a layer stack of one or more photovoltaic stacks of a photovoltaic module, and do not show interconnections of a multiple cells of a photovoltaic module. Examples of interconnections are discussed below with respect to FIGS. 8A-8D.

First, in FIG. 3A, a photovoltaic module 116 including a top electrode 122, bottom electrode 128 and thin film photovoltaic layers 124 disposed between the top electrode 122 and the bottom electrode 128. An exterior pane 112 is depicted to show the relative positions of the components of the photovoltaic module 116 in a multi-functional window. The thin film photovoltaic layers 124 are one or more layers of materials configured to absorb solar energy and convert it to electric energy by the photoelectric effect. Any type of thin film photovoltaic material can be used, including semiconductor materials, light adsorbing dyes, and organic polymers that exhibit the photoelectric effect. In some implementations, the thin film photovoltaic layers 124 include one or more semiconductor junctions. Examples of thin film semiconductor materials include amorphous silicon (a-Si), crystalline silicon (c-Si), including micro-crystalline Si and polycrystalline Si, gallium arsenide (GaAs), copper indium gallium selenide (CIGS), copper indium selenide (CIS), cadmium telluride (CdTe), cadmium sulfate (CdS), and zinc sulfide (ZnS). For example, CdTe and CdS layers may form a p-n junction. In another example, doped a-Si layers may form a p-i-n junction. A semiconductor junction can be a homojunction in a single material or a heterojunction between two layers of different materials, according to the desired implementation.

The top electrode 122 is configured to transmit light such that it can reach and be absorbed by the thin film photovoltaic layers 124. The bottom electrode 128 is also configured to transmit light such that the photovoltaic module 116 can transmit incident light that is not absorbed by the thin film photovoltaic layers 124. Example materials for these electrodes include transparent conducting oxides (TCO's), thin conductive grids, other arrangements of thin conductive wires, and combinations thereof. In some implementations, thin conductive grids can be specular. The photovoltaic module 116 can also include other materials or layers, including layers interposed between or adjacent to any of the components depicted in FIG. 3A. Examples of other layers that may be incorporated into a photovoltaic module 116 include current collectors, interconnects, and light filters.

FIG. 3B shows an example of a photovoltaic module 116. The photovoltaic module 116 includes a TCO anode 130, an n-type semiconductor layer 132, a p-type semiconductor layer 134, a TCO buffer layer 136 and a metal grid cathode 138. The TCO anode 130 is adjacent to an exterior pane 112. Examples of TCO's include zinc oxide (ZnO), aluminum-doped zinc oxide (Al-doped ZnO or AZO), indium tin oxide (ITO) gallium doped zinc oxide (Ga-doped ZnO), and fluorine-doped tin oxide (FTO). Thin film photovoltaic layers 124 include the n-type semiconductor layer 132 and the p-type semiconductor layer 134. Examples of materials for the n-type semiconductor layer 132 include ZnS. Examples of materials for the p-type semiconductor 134 include CdTe and CIGS. In some implementations, the thin film photovoltaic layers 124 include only cadmium (Cd)-free materials. The metal grid cathode 138 acts as the bottom electrode, with the TCO buffer layer 136 disposed between the thin film photovoltaic layers 124 and the metal grid cathode 138. The TCO buffer layer 136 can facilitate current collection.

FIG. 3C shows another example of a photovoltaic module 116. The photovoltaic module 116 includes a TCO anode 130, thin film photovoltaic layers 124, a TCO buffer layer 136 and a metal grid cathode 138, as discussed above with respect to FIG. 3B. In the example of FIG. 3C, the thin film photovoltaic layers 124 include a p-doped a-Si layer 140, an intrinsic a-Si layer 142, and an n-doped a-Si layer 144.

While FIGS. 3B and 3C provide examples of layer stacks, it is understood that various modifications can be made. For example, in some implementations, a thin wire current collector can be disposed between the TCO anode 130 and the exterior pane 112. Also, the thin film photovoltaic materials are not limited to the particular examples described above, but can be any type of thin film materials that exhibit the photovoltaic effect.

Example thicknesses of the thin film portions of a photovoltaic module, including thin film photovoltaic materials, TCO layers, and other thin film layers range from about 0.05 microns to about 10 microns. Example thicknesses of thin film photovoltaic materials range from 0.05 microns to about 5 microns. Example thicknesses of a TCO layer ranges from about 0.05 microns to about 1 micron. Example thicknesses of a metal grid range from about 10 microns to about 500 microns.

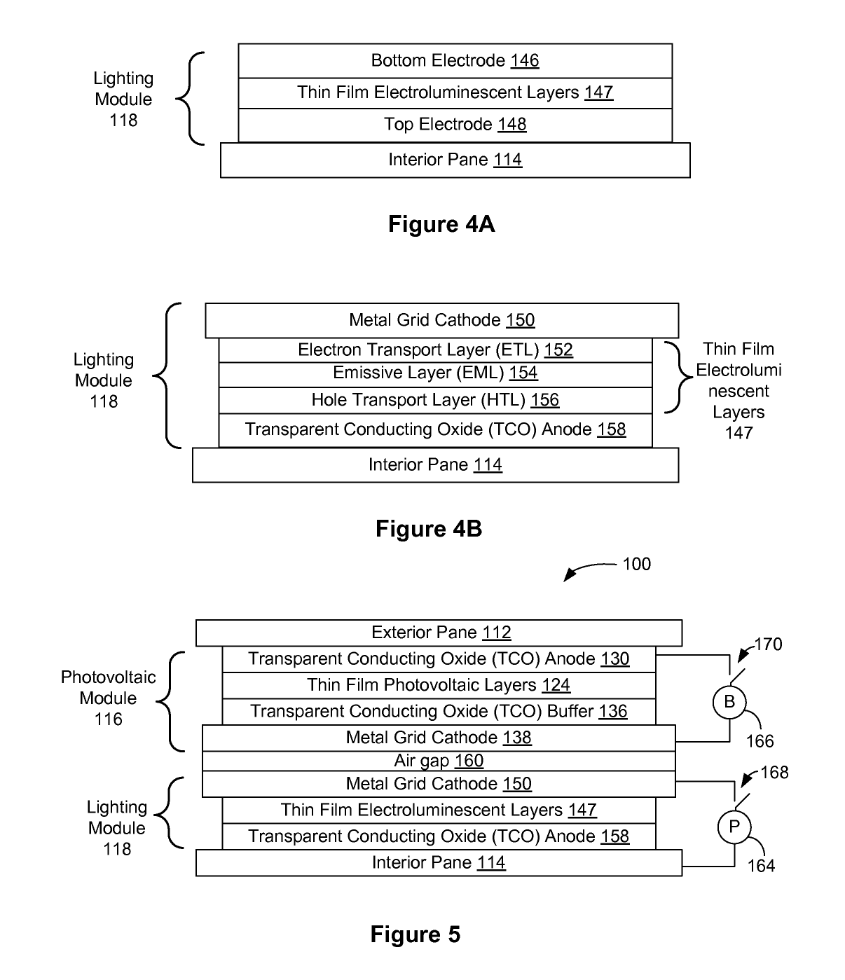

FIGS. 4A and 4B shows examples of cross-sectional schematic illustrations of a lighting module of a multi-functional window. In FIG. 4A, a lighting module 118 including a top electrode 148, a bottom electrode 146, and thin film electroluminescent layers 147 disposed between the top electrode 148 and the bottom electrode 146 is depicted. An interior pane 114 is depicted to show the relative positions of the components of the lighting module 118 in a multi-functional window. The thin film electroluminescent layers 147 can be one or more layers of materials configured to emits light in response to an electrical current. Any type of electroluminescent material can be used, including inorganic, organic, and polymeric materials.

The top electrode 148 is configured to transmit emitted light such that it can reach and be transmitted through interior pane 114. The bottom electrode 146 is also configured to transmit light such that the lighting module 118 can transmit incident light. Example materials for these electrodes include transparent conducting oxides (TCO's), thin conductive grids, other arrangements of thin conductive wires, and combinations thereof. The lighting module 118 can also include other materials or layers, including layers interposed between or adjacent to any of the components depicted in FIG. 4A. An example of such a component is a light filtering layer.

FIG. 4B shows an example of a lighting module 118 including organic light emitting diode materials. The lighting module 118 includes a TCO anode 158, a hole transport layer (HTL) 156, an emissive layer (EML) 154, an electron transport layer (ETL) 152, and a metal grid cathode 150.

Examples of TCO's include ZnO, AZO, ITO, Ga-doped ZnO, and FTO. Examples of ETL's include metal chelates, oxadiazoles, and imidazoles, with specific examples including 1,3,5-tris(N-phenylbenzimidazol-2-yl)benzene (TPBi), 1,2,4-triazole (TAZ) and derivatives thereof. Examples of HTL's include arylamines, isoindole, biphenyl diamine derivatives, starburst amorphous molecules, and spiro-linked molecules, with a specific example being N,N′-bis(naphthalen-1-yl)-N′-bis(phenyl)benzidine (NPB). Examples of EML's include fluorescent and phosphorescent dyes, metal chelates, carbozole, maleimide, and anthracene. Examples of fluorescent dyes include perylene, rubrene, and quinacridone derivatives. Phosphorescent dyes can be chosen from iridium complexes and other complexes based on heavy metals such as platinum. Additional examples of EML's include (8-hydroxyquinoline) aluminum (AlQ), iridium-tris(2-phenylpyidine) (Ir(ppy)₃) and poly[2-methoxy-5-(20-ethyl-hexyloxy)-1,4-phenylene-vinylene] (MEH-PPV).

In some implementations, thin film electroluminescent materials can include a light-emitting polymer (LEP). For example, the thin film electroluminescent layers 147 in FIGS. 4A and 4B can include an LEP and a hole injection layer (HIL). Examples of LEP's include poly(p-phenylene vinylene), poly(naphthalene vinylene), polyfluorene and derivatives thereof. Examples of HIL's include conductive polymers such as poly(3,4-ethylenedioxythiophene): poly(styrene sulfonic acid).

In some other implementations, an inorganic electroluminescent material is used. However, unlike organic electroluminescent materials, most inorganic electroluminescent materials are not transparent to the visible spectrum. If a non-transparent electroluminescent material is used, a lighting module configuration that allows light to pass between separated stacks of electroluminescent thin film layers can be used. Examples of inorganic electroluminescent materials include manganese-doped zinc sulfide (Mn-doped ZnS), indium phosphide (InP), gallium nitride (GaN), aluminum gallium arsenide (AlGaAs), gallium arsenide phosphide (GaAsP), aluminum gallium indium phosphide (AlGaInP), gallium(III) phosphide (GaP), indium gallium nitride (InGaN), aluminum gallium phosphide (AlGaP), zinc selenide (ZnSe), GaAs, and silicon carbide (SiC).

Example thicknesses of the thin film portions of a lighting module, including thin film electroluminescent layers, TCO layers, and other thin film layers range from about 1 nm and 1 micron. Example thicknesses of thin film electroluminescent materials range from about 1 nm to 300 nm, for example, between about 5 nm and 100 nm. Example thicknesses of a TCO layer ranges from about 0.05 microns to about 1 micron. Example thicknesses of a metal grid range from about 50 microns to about 500 microns.

In some implementations, a photovoltaic module and a lighting module of a multi-functional window can share an electrode. In some other implementations, a photovoltaic module and a lighting module have separate electrodes. FIG. 5 shows an example of a schematic illustration of a multi-functional window including two metal grid cathodes. A multi-functional window 100 includes a photovoltaic module 116 and a lighting module 118 separated by an air gap 160 and located between an exterior pane 112 and an interior pane 114. The photovoltaic module 116 includes a TCO anode 130, thin film photovoltaic layers 124, a TCO buffer layer 136, and a metal grid cathode 138. A circuit including a battery 166 connected to TCO anode 130 and metal grid cathode 138 is depicted, with a switch 170 operable to activate the photovoltaic module 116 to charge the battery 166. The photovoltaic module can also be connected to other photovoltaic modules in an array, to a power grid, or other desired external connection point.

The lighting module 118 includes a TCO anode 158, thin film electroluminescent layers 147, and metal grid cathode 150. A circuit including a power source 164 connected to TCO anode 158 and metal grid cathode 150 is depicted, with a switch 168 operable to activate the lighting module 118. In some implementations, the lighting module 118 can be connected to the battery 166 that is connected to the photovoltaic module 116, such that the photovoltaic module 116 provides power to the lighting module 118. In some other implementations, the power source 164 can be a different battery or the main building power source, for example.

The air gap 160 electrically insulates metal grid cathode 138 from metal grid cathode 150. In some implementations, the metal grid cathodes 138 and 150 have the same wire and grid dimensions, and are aligned to minimize impeding light transmission. The particular arrangement of the layers of each of the photovoltaic module 116 and lighting module 118 can be modified according to the desired implementation. The configuration in FIG. 5 allows the multi-functional window to simultaneously be in a photovoltaic state and lighting state if desired. Table 2, below, shows switch configurations for various states of the multi-functional window 100 shown in FIG. 5.

TABLE 2
Switch Configurations of a Dual Cathode Multi-Functional Window

| | Neutral State | Photovoltaic State | Lighting State |
|---|---|---|---|
| Switch 168 | Off | On/Off | On |
| Switch 170 | Off | On | On/Off |

Both switches 168 and 170 are off when the multi-functional window 100 is in a neutral state. In a photovoltaic state, the switch 170 is on, while the switch 168 can be on or off according to whether a user concurrently wants light to be emitted from the multi-functional window 100. In a lighting state, the switch 168 is on, while the switch 170 can be on or off according to whether a user concurrently wants photovoltaic power generation.

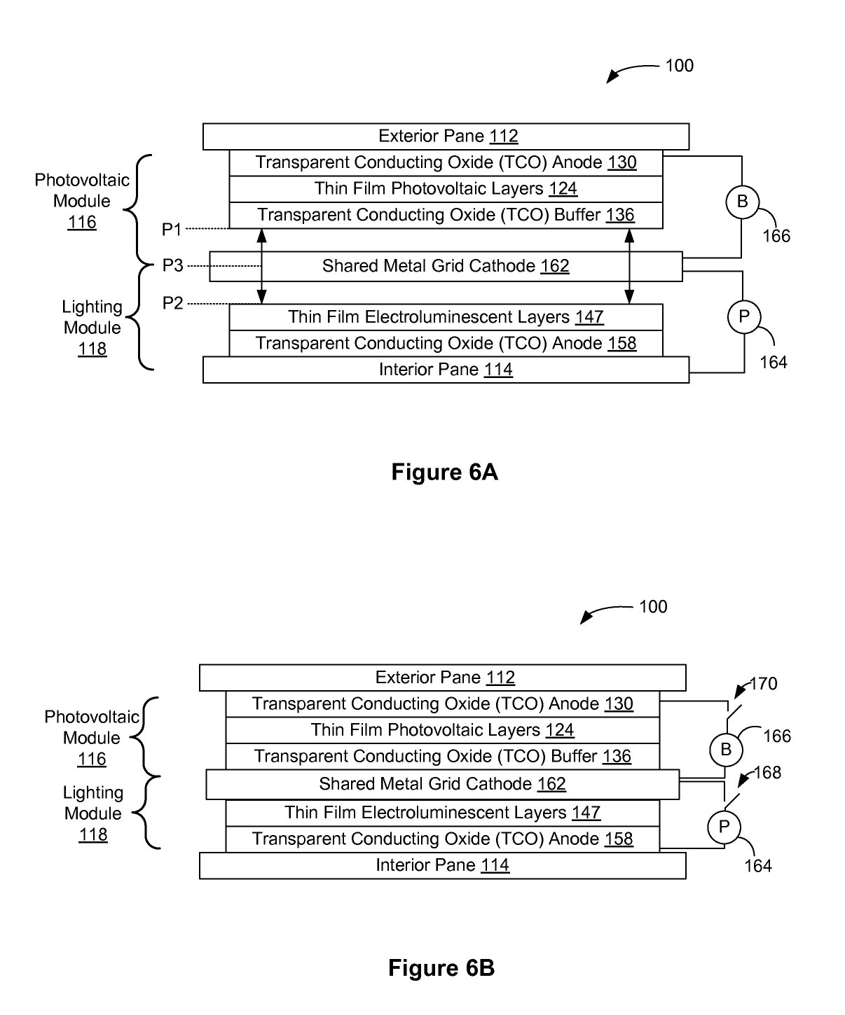

In implementations in which a photovoltaic module and a lighting module share an electrode, the multi-functional window can include a switching mechanism to switch the shared electrode between the photovoltaic module and the lighting module. FIGS. 6A and 6B show examples of schematic illustrations of multi-functional windows having various state-switching configurations. First, in FIG. 6A, a multi-functional window 100 includes a photovoltaic module 116 and a lighting module 118 between an exterior pane 112 and an interior pane 114. The photovoltaic module 116 includes a TCO anode 130, thin film photovoltaic layers 124, and a TCO buffer layer 136. The lighting module 118 includes a TCO anode 158 and thin film electroluminescent layers 147. The photovoltaic module 116 and the lighting module 118 share a metal grid cathode 162. In the example of FIG. 6A, the shared metal grid cathode 162 is movable between the photovoltaic module 116 and the lighting module 118. In some implementations, the shared metal grid cathode 162 is movable between three positions: contacting the TCO buffer layer 136 of the photovoltaic module 116 (labeled P1), contacting the thin film electroluminescent layers 147 (P2), and contacting neither the TCO buffer layer 136 nor the thin film electroluminescent layers 147 (P3). The shared metal grid cathode 162 is depicted in P3 in the example of FIG. 6A. In P1, a circuit including a battery 166 is completed, activating the photovoltaic module 116. In P2, a circuit including a power source 164 is completed, activating the lighting module 118. In P3, neither the photovoltaic module 116 nor the lighting module 118 is activated. Table 3, below, summarizes states of a multi-functional window with a movable shared cathode as depicted in FIG. 6A in various positions:

TABLE 3
States of a Movable Shared Cathode Multi-Functional Window

| Movable Cathode | | | |
|---|---|---|---|
| Position | Neutral State | Photovoltaic State | Lighting State |
| P1 | No | Yes | No |
| P2 | No | No | Yes |
| P3 | Yes | No | No |

The shared metal grid cathode 162 can be moved by a user applying physical force, for example via a lever, to the shared metal grid cathode in some implementations. In some other implementations, an electrically activated motive force can be used to move the shared metal grid cathode 162.

In implementations that include multiple multi-function windows, arranged for example in an array, the states of the multiple multi-function windows can be activated or deactivated simultaneously or individually according to the desired implementation. For example, in some implementations, a single lever may be used to activate or deactivate all or a subset of the photovoltaic modules or lighting modules simultaneously. In some other implementations, multiple individual levers may be used to activate or deactivate the photovoltaic modules or lighting modules of individual multi-function windows, rows of multi-function windows, or other configuration as desired.

FIG. 6B depicts a multi-functional window 100 including a photovoltaic module 116 and a lighting module 118 between an exterior pane 112 and an interior pane 114. The photovoltaic module 116 includes a TCO anode 130, thin film photovoltaic layers 124, and a TCO buffer layer 136. The lighting module 118 includes a TCO anode 158 and thin film electroluminescent layers 147. The photovoltaic module 116 and the lighting module 118 share a metal grid cathode 162. The metal grid cathode 162 is in a fixed position in the example of FIG. 6B.

A circuit including a battery 166 connected to the TCO anode 130 and the shared metal grid cathode 162 is depicted, with a switch 170 operable to activate the photovoltaic module 116. Another circuit including a power source 164 connected to the TCO anode 158 and the shared metal grid cathode 162 is depicted, with a switch 168 operable to activate the lighting module 118. In some implementations, the switches 168 and 170 are configured such that only one can be switched on at a time to prevent shorting of the other circuit. In some implementations, the lighting module 118 can be connected to the battery 166 (connected to the photovoltaic module 116), such that the photovoltaic module 116 provides power to the lighting module 118.

Table 4, below, shows switch configurations for various states of the multi-functional window 100 shown in FIG. 6B.

TABLE 4
Switch Configurations of a Shared Cathode Multi-Functional Window

| | Neutral State | Photovoltaic State | Lighting State |
|---|---|---|---|
| Switch 168 | Off | Off | On |
| Switch 170 | Off | On | Off |

Both switches 168 and 170 are off when the multi-functional window 100 is in a neutral state. In a photovoltaic state, the switch 170 is on and the switch 168 off. In a lighting state, the switch 168 is on and the switch 170 is off. In some implementations, the multi-functional window 100 includes circuitry such only one of the photovoltaic module 116 and the lighting module 118 can be activated at any one time.

In implementations that include multiple multi-function windows, arranged for example in an array, the states of the multiple multi-function windows can be activated or deactivated simultaneously or individually according to the desired implementation. For example, in some implementations, a single switch may be used to activate or deactivate all or a subset of the photovoltaic modules or lighting modules simultaneously. In some other implementations, multiple individual switches may be used to activate or deactivate the photovoltaic modules or lighting modules of individual multi-function windows, rows of multi-function windows, or other configurations as desired.

A multi-functional window as described herein can be of any size according to the desired implementation. For example, in some implementations, a multi-functional window can range anywhere from tens of centimeters to over 1 meter in each of length and width. Example areas can range from one hundred square centimeters to several square meters.

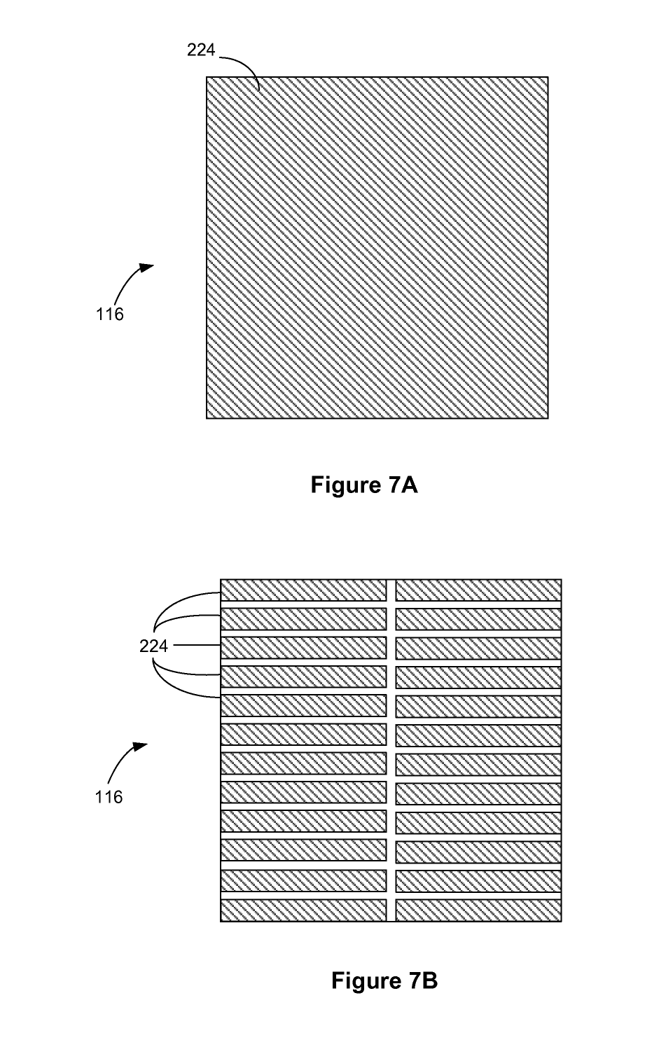

A photovoltaic module can include one or more individual photovoltaic cells. In some implementations, for example, a photovoltaic module can include a single photovoltaic cell. In such implementations, each of thin film photovoltaic layers can be continuous across the entire active portion of the multi-functional window. In some other implementations, a photovoltaic module can include multiple stacks of thin film photovoltaic layers. FIGS. 7A and 7B show examples of schematic illustrations of top (external pane-facing) views of photovoltaic modules of a multi-functional window. In FIG. 7A, thin film layers photovoltaic layers are continuous across the photovoltaic module 116, acting as a single photovoltaic cell 224. In FIG. 7B, thin film photovoltaic layers are separated into individual stacks, forming multiple photovoltaic cells 224. In some implementations, a number of cells in a photovoltaic module 116 can depend on the module area. For example, larger modules can include a greater number of cells. Multiple cells can be beneficial in some implementations for larger modules for several reasons including voltage and defect management. As an area of a photovoltaic module increases, the total power generated by the module can increase proportionally. A single cell across a larger area will produce power at a larger voltage than multiple individual cells connected in series across the same area, which may not be desirable depending on the particular implementation. Accordingly, in some implementations, a photovoltaic module can include multiple cells connected in series. Multiple cells can also be advantageous to minimize disruption to a photovoltaic module due to a shunt or other disabling defect. If a shunt develops in a large area photovoltaic module having a single cell, it can risk disabling the entire photovoltaic module. Multiple cells can allow a single isolated cell to be disabled without affecting operation of the remainder of the photovoltaic module.

FIGS. 8A-8D show examples of schematic illustrations of cross-sectional views of photovoltaic modules including multiple photovoltaic cells and equivalent circuit diagrams of the same. First, in FIG. 8A, a photovoltaic module 116 including a cathode 138 and individual photovoltaic cells 224. Each photovoltaic cell 224 includes a TCO anode 130, thin film photovoltaic layers 124, and a TCO buffer layer 136. Each photovoltaic cell 224 is connected to a lead 230 (schematically shown connecting all TCO anodes 130), which can be routed through a frame of a multi-functional window for aesthetic reasons and to minimize light obstruction. FIG. 8B shows an example of an equivalent circuit diagram of the photovoltaic cells 224 in FIG. 8A connected in parallel. In the example of FIG. 8A, the photovoltaic cells 224 are connected in parallel by the metal cathode 138. In some implementations, the photovoltaic module 116 can include one or more additional electrical components (not shown) such as diodes, inverters, converters, and the like. For example, in some implementations, the photovoltaic module 116 can include one or more inverters (not shown) including components to step down voltage. An inverter can be included at each of the photovoltaic cells 224 or at every two or more of the photovoltaic cells 224 according to the desired implementation.

FIG. 8C shows an example of a photovoltaic module 116 including multiple photovoltaic cells 224 connected in series. In the example of FIG. 8C, each photovoltaic cell 224 includes a TCO anode 130, thin film photovoltaic layers 124, and a TCO buffer layer 136 on a metal grid cathode 138. The metal grid cathode 138 includes dielectric gaps 232 to electrically isolate the photovoltaic cells 224 and allow the photovoltaic cells 224 to be connected in series. The dielectric gaps 232 can be air gaps or a dielectric material such as glass, according to the desired implementation. The photovoltaic cells 224 are connected in series by interconnects 234. Examples of interconnects 234 include thin conductive wires or TCO layers. In some implementations, the interconnects 234 are integral parts of a component including the metal grid cathode 138. Each interconnect 234 connects the TCO anode 130 of a photovoltaic cell 224 to the metal cathode 138 of the adjacent cell. FIG. 8D shows an example of an equivalent circuit diagram of the photovoltaic cells 224 in FIG. 8B connected in series. As indicated above, in some implementations, connecting the photovoltaic cells 224 in series can be useful for voltage step-down.

While FIGS. 8A-8D provide examples of electrical connection configurations of photovoltaic cells of a photovoltaic module, other configurations can be implemented to achieve the desired current and voltage for the photovoltaic module. For example, a photovoltaic module can include photovoltaic cells in a series-parallel configuration having multiple arrays of photovoltaic cells connected in series where the arrays are then connected in parallel.

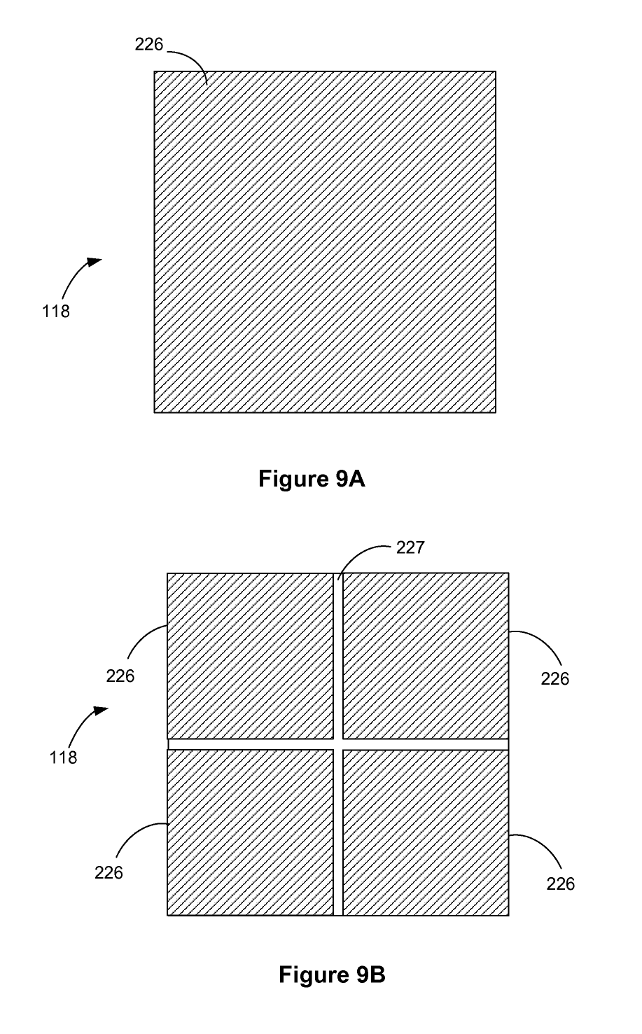

In some implementations, a lighting module can include one or more individual electroluminescent stacks. In some implementations, for example, a lighting module can include a single electroluminescent stack. In such implementations, each of thin film electroluminescent layers of a lighting module can be continuous across the entire active luminescent portion of the multi-functional window. In some other implementations, a lighting module can include multiple individual luminescent stacks, each of which is configured to emit light. FIGS. 9A and 9B show examples of schematic illustrations of top (internal pane-facing) views of lighting modules of a multi-functional window. In FIG. 9A, electroluminescent thin film layers are continuous across the lighting module 118, acting as a single lighting unit 226. In FIG. 9B, electroluminescent thin film layers are separated into individual stacks, forming multiple lighting units 226. In some implementations, for example, a TCO anode layer of each lighting unit 226 can be independently connected to a power source. Such an arrangement can be implemented, for example, to reduce ohmic losses across a TCO anode layer or to facilitate fabrication. Non-light emissive areas 227 of the lighting module 118 can include no materials or any appropriate transparent non-emissive materials according to the desired implementation. In some implementations, additional conductive metal lines can be routed to different regions of a continuous TCO anode. This can be done to reduce ohmic losses instead of or in addition to fabricating multiple lighting units, for example.

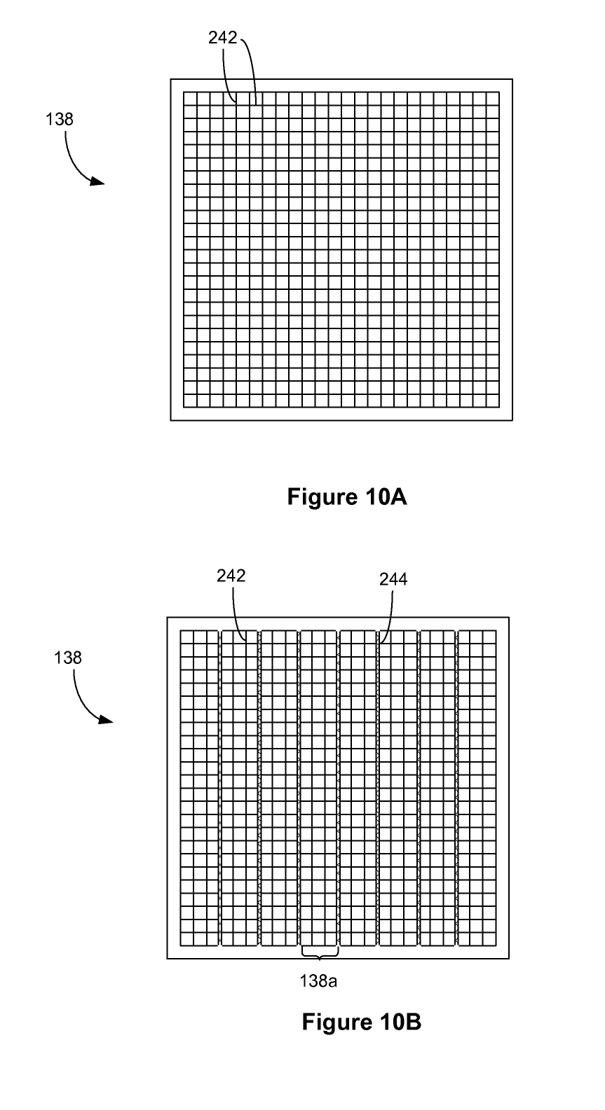

FIGS. 10A and 10B show examples of schematic illustrations of a top view of a cathode of a multi-functional window. In FIG. 10A, a metal grid cathode 138 including wires 242 arranged in a regular pattern is shown. The wires 242 can be any appropriate metal, including metal alloys. Examples of metals include silver (Ag), copper (Cu), aluminum (Al), gold (Au), and brass. Wire size can be selected based on factors including transparency and current capacity. Thinner wires improve transparency, while thicker wires improve current capacity. The thickness of the wires 242 can range for example from about 50 microns to about 500 microns, though other sizes may be used according to the desired implementation. In some implementations, a wire having an American Wire Gauge (AWG) of between about 24 and 50 can be used. While the metal grid cathode 138 in the example of FIG. 10A is arranged in a pattern of squares, a grid of a metal grid cathode can be of any appropriate pattern. For example, a grid can have a honeycomb pattern, a pattern of S-shapes, or other pattern according to the desired implementation. In some implementations, an irregularly patterned metal grid cathode can be used.

In some implementations, a grid can be arranged to facilitate one or more of current collection from a photovoltaic module, current distribution to a lighting module, photovoltaic cell separation, photovoltaic cell interconnection and the like. FIG. 10B, for example, depicts a metal grid cathode 138 including insulated components 244 interposed between every third vertically-oriented wire of the wires 242, forming multiple electrically isolated grid portions 138a. Such a configuration can be used for example to electrically separate adjacent photovoltaic cells as described with respect to FIG. 8C, above. In some other implementations, insulated components can be interposed between horizontally-oriented wires as well, for example, to form square-shaped isolated grid portions.

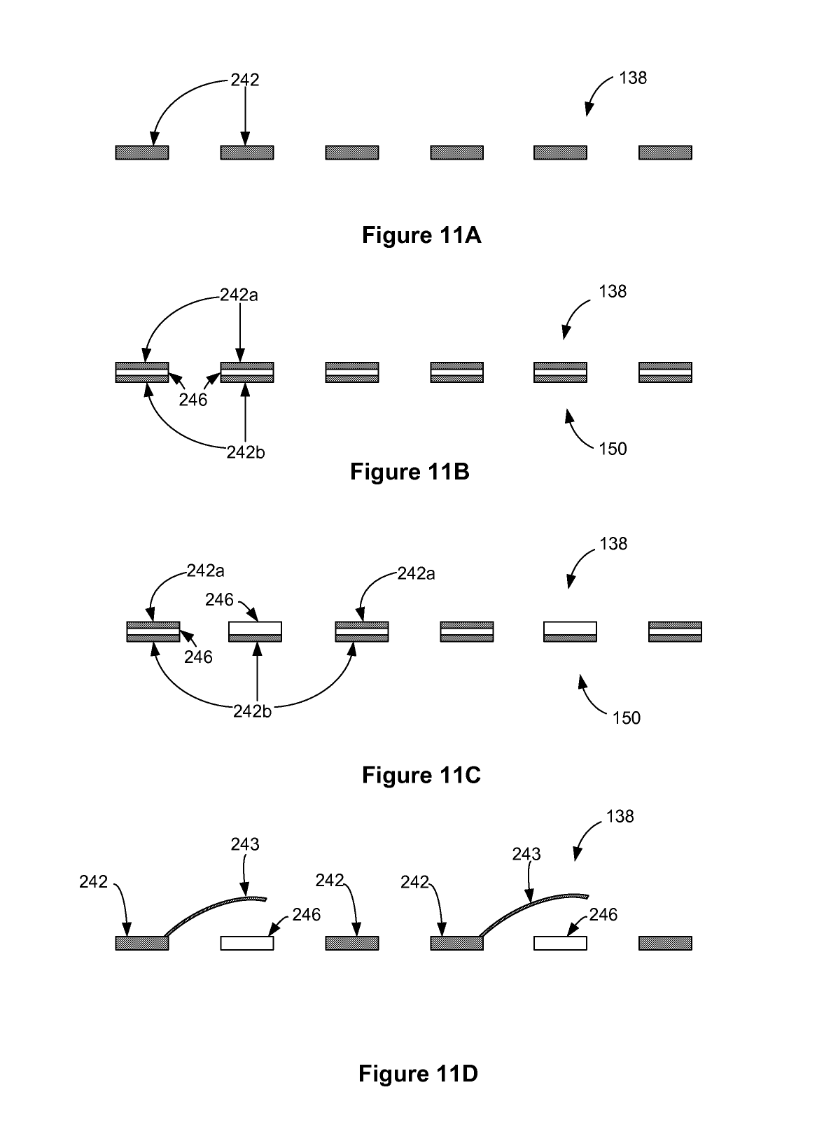

FIGS. 11A-11D show examples of schematic illustrations of a cross-sectional view of portions of cathodes of multi-functional windows. FIG. 11A shows a cross-sectional view of a portion of a metal cathode grid cathode 138 including wires 242. The wires 242 in the example of FIG. 11A are shown as rectangular in cross-section, however, in some other implementations, it may be non-rectangular in cross-section. For example, it may be circular or any other shape in cross-section according to the desired implementation. In the example of FIG. 11A, the wires 242 include only metal. The metal grid cathode 138 can be a shared cathode, such as those described with reference to FIGS. 6A and 6B, or a cathode used exclusively for either a photovoltaic module or a lighting module, such as those described above with respect to FIG. 5. FIG. 11B shows a cross-sectional view of metal wires 242a and 242b separated by dielectric material 246. The dielectric material can be any transparent or non-transparent dielectric material, including glass or plastic, which can electrically isolate the wires 242a from the wires 242b. The wires 242a and 242b are effectively parts of two separate cathodes: a metal grid cathode 138, which includes the wires 242a and a metal grid cathode 150, which includes the wires 242b. The metal grid cathode 138, for example, can be a cathode for a photovoltaic module and the metal grid cathode 150, for example, can be a cathode for a lighting module. A configuration as shown in the example of FIG. 11B can be used in a similar manner to the metal grid cathodes 138 and 150 depicted in FIG. 5, with the dielectric material 246 providing electrical isolation rather than the air gap 160 shown in FIG. 5. Providing electrically separated metal grid cathodes as a single component can facilitate fabrication and reduce window thickness according to the desired implementation. FIG. 11C shows a cross-sectional view of portions of metal grid cathodes 138 and 150. Similar to the example of FIG. 11B, the metal grid cathodes 138 and 150 in the example of FIG. 11C are a single component, which includes metal wires 242a of the metal grid electrode 138 electrically isolated from metal wires 242b of the metal grid cathode 150 by a dielectric material 246. In the example of FIG. 11C, the dielectric material 246 functions to separate the metal grid cathode 138 into multiple electrically separated portions. A configuration as shown in the example of FIG. 11C can be used to provide a different metal grid pattern on each side of the dielectric material 246, for example for each of the photovoltaic module and the lighting module. FIG. 11D shows a cross-sectional view of a portion of a metal grid cathode 138 including wires 242 and dielectric material 246. The metal grid cathode 138 also includes interconnects 243, which can be configured to contact adjacent photovoltaic cells, for example as depicted in FIG. 8C.

In some implementations, metal wires such as those described with reference to FIGS. 11A-11D can include patterned metal lines and traces. For example, in some implementations, a metal grid can be formed by depositing a first layer of metal, depositing a layer of dielectric material on the first metal layer, then depositing a second layer of metal. The deposited layers can be patterned in one or more operations to form a configuration as shown in FIGS. 11A-11C.

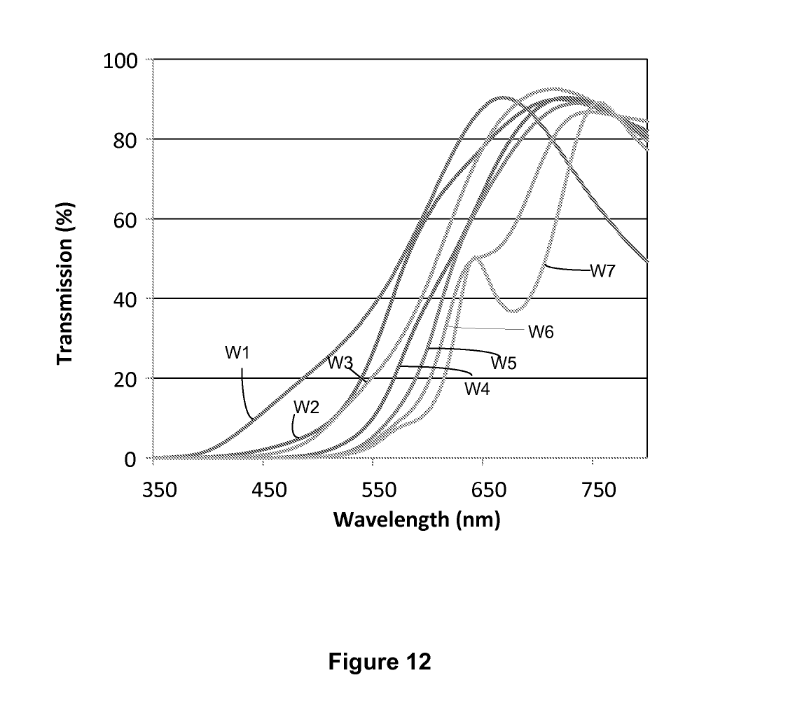

As indicated above, in some implementations, the multi-functional windows described herein transmit a portion of incident light. Note that unlike conventional photovoltaics, which are designed to absorb as much incident light as possible, the photovoltaic modules described herein can transmit 10% to 90% of incident light, and in some implementations, 20% to 70% or 20% to 50% of incident light. The total light transmission can be controlled by the thickness of the photovoltaic thin film layers. The color appearance of the transmitted light also can be controlled by the thickness of the photovoltaic thin film layers. FIG. 12 is a graph depicting the light transmission percentages of windows including photovoltaic thin film layers of different thicknesses as determined by simulation. The curves, labeled W1-W7, each represent the transmission percentage of a different window across a range of light wavelengths. Table 5 below shows the thicknesses of photovoltaic and lighting module layers for each window W1-W7.

TABLE 5
Thin Film Layer Thicknesses (nm) of Different Windows

| | Layer | W1 | W2 | W3 | W4 | W5 | W6 | W7 |
|---|---|---|---|---|---|---|---|---|
| PV | ITO | 50 | 105 | 100 | 100 | 100 | 140 | 140 |
| module | p a-Si | 5 | 5 | 5 | 5 | 5 | 5 | 5 |
| | i a-Si | 50 | 70 | 100 | 200 | 300 | 300 | 300 |
| | n a-Si | 10 | 10 | 15 | 15 | 15 | 15 | 15 |
| | AZO | 50 | 105 | 100 | 100 | 100 | 100 | 140 |
| Lighting | AIQ | 60 | 60 | 60 | 60 | 60 | 60 | 60 |
| Module | NPB | 50 | 50 | 50 | 50 | 50 | 50 | 50 |
| | ITO | 100 | 100 | 100 | 100 | 100 | 100 | 100 |

Total thickness of the thin film layers of the photovoltaic module ranged from 165 nm (W1) to 600 nm (W7). Thickness of the a-Si thin film photovoltaic layers was varied from 65 nm (W1) to 320 nm (W7). Table 6 shows the simulated CIE 1931 color coordinates, color appearance and average light transmission for each window.

TABLE 6
Color and Light Transmission Characteristics of Different Windows

| | CIE 1931 Color | | | Average |
|---|---|---|---|---|
| | Coordinates | | | Transmission |
| Window | x | y | Color Appearance | (%) |
| W1 | 0.457 | 0.412 | white | 50.1 |
| W2 | 0.532 | 0.429 | yellowish orange | 49.2 |
| W3 | 0.544 | 0.429 | yellowish orange | 46.4 |
| W4 | 0.591 | 0.404 | orange | 41.9 |
| W5 | 0.624 | 0.374 | reddish orange | 39.2 |
| W6 | 0.627 | 0.371 | reddish orange | 34.6 |
| W7 | 0.627 | 0.370 | reddish orange | 29.2 |

Average transmission was calculated by transfer matrix simulation. The thickness of the thin film photovoltaic layers used to obtain a desired color appearance and transmission can depend on the particular photovoltaic materials used.

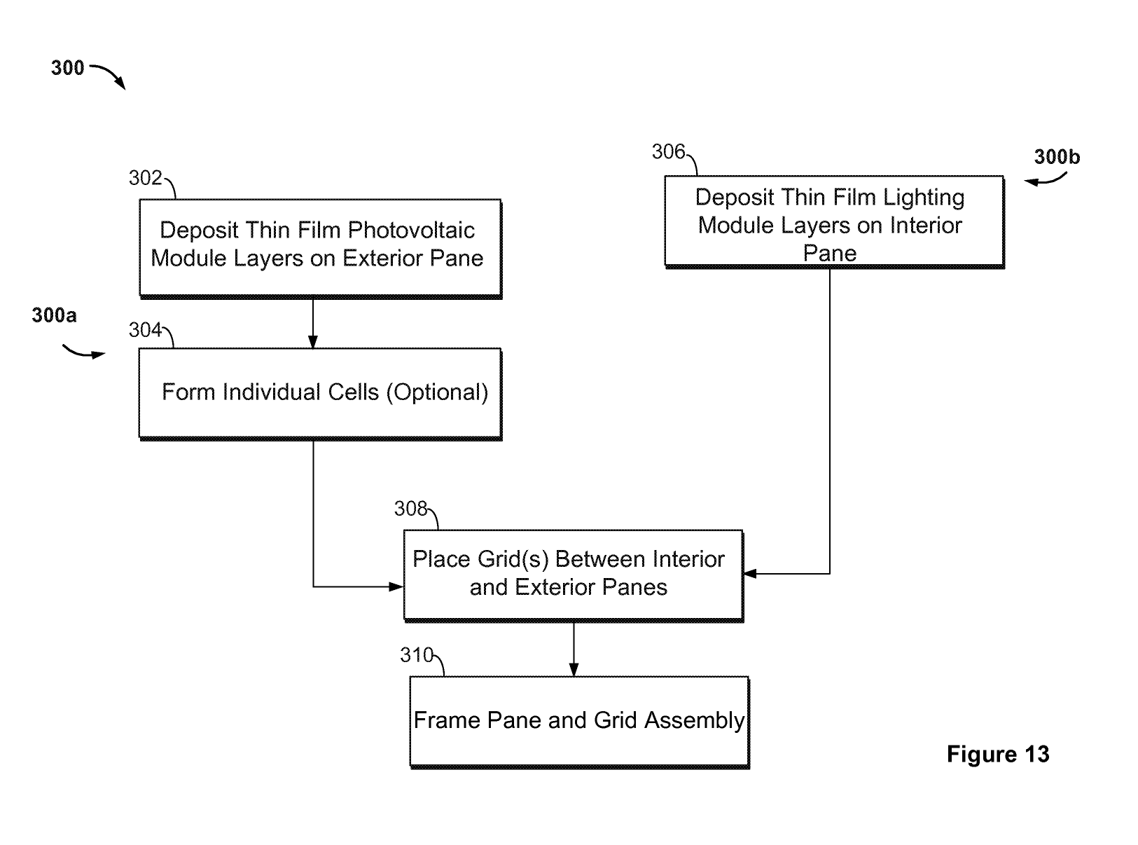

FIG. 13 shows an example of a flow diagram illustrating a manufacturing process for a multi-functional window. The process 300 includes parallel processes 300a and 300b, with the process 300a involving thin film deposition on an exterior pane, and the process 300b involving thin film deposition on an interior pane. The process 300a begins at block 302 with deposition of thin film layers for a photovoltaic module on an exterior pane. Thin film layers for a photovoltaic module can include one or more of thin film photovoltaic layers, a TCO anode layer and a TCO buffer layer. In some implementations, an exterior pane may be provided with one or more of these layers. For example, an exterior pane may be provided with a TCO anode layer. Any appropriate deposition technique including chemical vapor deposition (CVD), physical vapor deposition (PVD) including sputtering and evaporation techniques, and atomic layer deposition (ALD) can be used. In some implementations, one or more patterning techniques including the use of masked deposition or removal of deposited material can be used to achieve a desired pattern. The process 300a continues at block 304 with forming individual photovoltaic cells. Block 304 is optional and is not performed in some implementations, for example, if multiple individual cells are not desired or are formed by patterning in block 302. Block 304 can involve scanning a laser beam along one or more scribe lines to ablate the thin film photovoltaic layers along the one or more scribe lines. In some implementations, the thin film photovoltaic layers can be completely ablated such that the underlying exterior pane is exposed. In some other implementations, one or more of the thin film photovoltaic layers can be left wholly or partially intact. For example, in some implementations, a TCO anode or buffer can be left intact. Block 304 can be performed from the front side such that the laser beam originates from the thin film side of the exterior pane, or from the back side such that the laser beam passes through the exterior pane prior to reaching thin film layers, according to the desired implementation. Example laser scribe line widths range from about 50 to 150 microns, though narrower or wider widths may be used according to the desired implementation.

The process 300b includes deposition of thin film layers for a lighting module on an interior pane at block 306. Thin film layers for a lighting module can include one or more of thin film electroluminescent layers and a TCO anode layer. In some implementations, an interior pane may be provided with one or more of these layers. For example, an interior pane may be provided with a TCO anode layer. Block 306 can involve any appropriate deposition technique including CVD, PVD and ALD techniques. In some implementations, one or more patterning techniques including the use of masked deposition or removal of deposited material can be used to achieve a desired pattern. Although not depicted, an optional laser scribing operation can be performed according to the desired implementation.

The process 300 then continues at block 308 with placing one or more metal grids between the interior and exterior panes to form a pane and grid assembly. In some implementations, block 308 can involve placing an already formed grid between the exterior and interior panes. In some other implementations, block 308 can involve depositing metal material on thin film layers on one or more of the exterior and interior panes. In some implementations, deposition of metal material can include one or more patterning techniques including the use of masked deposition or removal of deposited material can be used to achieve a desired pattern. In some other implementations, deposition of metal material can include printing metal lines in a desired pattern. The process 300 then continues at block 310 with framing the pane and grid assembly. Various assembly operations in blocks 308 and 310 can be performed in any order according to the desired implementation. For example, in some implementations, a frame may be placed around one or more of the exterior pane and the interior pane prior to fully assembling the grid(s) and the panes. This can facilitate incorporating an air gap between a photovoltaic module and a lighting module, for example. Electrical components to provide external connection points to the photovoltaic module and lighting module can also be incorporated in the framed assembly at any appropriate point during assembly.

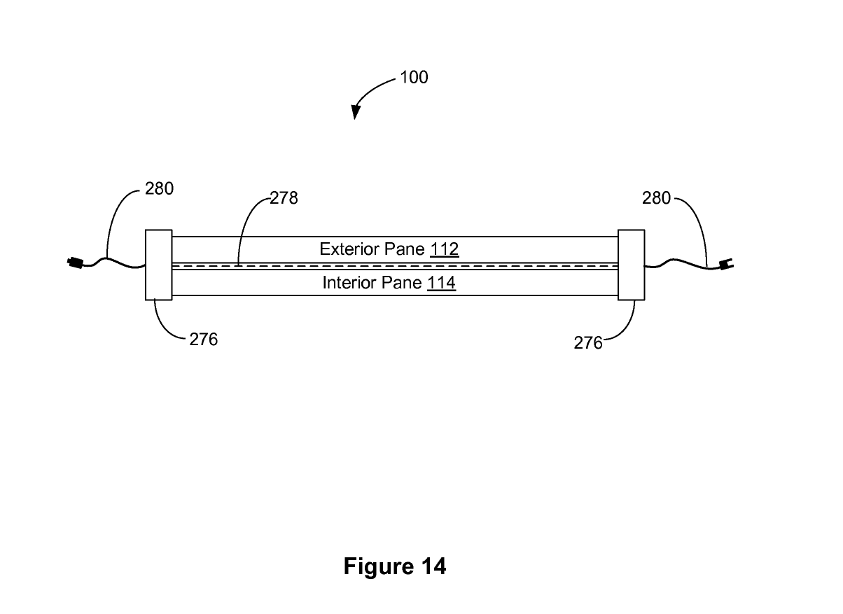

FIG. 14 shows an example of a cross-sectional schematic illustration of a multi-functional window. The multi-functional window 100 includes an exterior pane 112, an interior pane 114, and a grid 278. Thin film layers on the exterior pane 112 and the interior pane 114 are not depicted. The exterior pane 112, the interior pane 114, and the grid 278 are framed by frame 276. External electrical connectors 280 can be configured to connect to external power sources, batteries, grids, and/or other modules according to the desired implementation. In the example of FIG. 14, two external electrical connectors are shown, for example, one to lead into the multi-functional window 100 and one to lead out of the multi-functional window 100. In some implementations, a lead into the multi-functional window 100 can provide a lighting module with power. A lead out of the multi-functional window 100 can be used to pull power from a photovoltaic module. In some implementations, in and out leads for one or both of the photovoltaic and lighting modules may be used, for example, to interconnect the photovoltaic modules of multiple windows and/or interconnect the lighting modules of multiple windows. A multi-functional window 100 can include any number of external connectors according to the desired implementation. Each external electrical connector 280 may include multiple cables, for example, to provide independent electrical connection to each of the photovoltaic module and lighting modules.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A window comprising:
first and second transparent substrates;
a photovoltaic module disposed between the first transparent substrate and the second transparent substrate, the photovoltaic module including a first transparent electrode and one or more photovoltaic active thin film layers; and
a lighting module disposed between the first transparent substrate and second transparent substrate, the lighting module including a second transparent electrode and one or more electroluminescent active layers,
wherein each of the photovoltaic module and the lighting module further include a grid electrode disposed between the photovoltaic active thin film layers and the electroluminescent active layers.

2. The window of claim 1, wherein the window is configured to transmit at least a portion of incident light bi-directionally.

3. The window of claim 1, wherein the window is switchable between a photovoltaic state and a lighting state, wherein in the photovoltaic state, the window is operable to convert a first portion of incident light to electrical energy and transmit a second portion of incident light and wherein in the lighting state, the window is operable to generate and emit light.

4. The window of claim 3, wherein the second portion is between about 20% and 50% of the incident light.

5. The window of claim 3, wherein the window is further switchable to and from a neutral state, wherein in the neutral state, the window is electrically disconnected and transmits a portion of the incident light.

6. The window of claim 1, wherein the photovoltaic module and the lighting module share a grid electrode.

7. The window of claim 6, wherein the grid electrode is movable between first, second and third positions and wherein the window is in a photovoltaic state when the grid electrode in the first position, in a lighting state when the grid electrode is in the second position, and in a neutral state when the grid electrode is in the third position.

8. The window of claim 6, wherein the grid electrode is in a fixed position.

9. The window of claim 1, wherein the photovoltaic module and the lighting module have separate grid electrodes.

10. The window of claim 9, wherein the separate grid electrodes are separated by an air gap or a solid dielectric material.

11. The window of claim 1, wherein the grid electrode is divided into electrically separate portions.

12. The window of claim 1, wherein the window is configured such that the photovoltaic module provides power to the lighting module.

13. The window of claim 1, wherein the one or more photovoltaic active thin film layers include at least one semiconductor material selected from amorphous silicon (a-Si), crystalline silicon (c-Si), gallium arsenide (GaAs), copper indium gallium selenide (CIGS), copper indium selenide (CIS), cadmium telluride (CdTe), cadmium sulfate (CdS) and zinc sulfide (ZnS).

14. The window of claim 1, wherein the first transparent electrode and second transparent electrode include transparent conducting oxides.

15. The window of claim 1, wherein the one or more electroluminescent active layers include an electron transport layer (ETL), an emissive layer (EML) and a hole transport layer (HTL).

16. The window of claim 1, wherein the one or more electroluminescent active layers include a light-emitting polymer (LEP).

17. The window of claim 1, wherein the photovoltaic module includes a plurality of interconnected photovoltaic cells.

18. The window of claim 17, wherein the plurality of interconnected photovoltaic cells are interconnected in series.

19. An array of windows according to claim 1.

20. The array of claim 19, wherein the plurality of windows are electrically interconnected.

21. A window, comprising:
means for transmitting incident light;
means for generating power from incident light; and
means for producing lighting.

22. The window of claim 21, wherein the means for transmitting incident light include means for transmitting between about 20% and 50% of incident light.

23. The window of claim 21, further comprising means for switching between a photovoltaic state and a lighting state, wherein in the photovoltaic state, the window is operable to convert a first portion of incident light to electrical energy and transmit a second portion of incident light and wherein in the lighting state, the window is operable to generate and emit light.

24. A method, comprising:
depositing one or more thin film layers selected from a transparent conducting oxide layer and photovoltaic layers on a first transparent pane;
depositing one or more thin film layers selected from a transparent conducting oxide layer and electroluminescent layers on a second transparent pane; and
placing one or more metal grids between the thin film layers deposited on the first transparent substrate and the thin film layers deposited on the second transparent substrate to form a pane and grid assembly.

25. The method of claim 24, wherein placing one or more metal grids includes one of:
placing a formed metal grid between the thin film layers deposited on the first transparent substrate and the thin film layers deposited on the second transparent substrate, and
depositing metal on one or more of the thin film layers deposited on the first transparent substrate and the thin film layers deposited on the second transparent substrate.

26. The method of claim 24, further comprising framing the pane and grid assembly.
